(19) United States
(12) Patent Application Publication
(10) Pub. No.: US 2010/0068561 A1
(43) Pub. Date: Mar. 18, 2010

(54) PERMEATION PROTECTION FOR PRESSURIZED HYDROGEN STORAGE TANK

(75) Inventors: Thorsten Rohwer, Tamm (DE); Holger Eitel, Frankfurt AM Main (DE); Thorsten Michler, Hofheim (DE); Angela Frohlich, Ingelheim (DE)

Correspondence Address: General Motors Corporation;c/o REISING, ETHINGTON, BARNES, KISSELLE, P.C., P.O. BOX 4390, TROY, MI, 48099-4390, US

(73) Assignee: GM GLOBAL TECHNOLOGY OPERATIONS, INC., DETROIT, MI (US)

(21) Appl. No.: 12/209,670

(22) Filed: Sep. 12, 2008

(51) Int. Cl. H01M 8/02; B05D 7/22; C23C 16/513; C23C 14/34

(52) U.S. Cl. 429/12; 427/569; 427/115; 204/192.15

(57) ABSTRACT

One embodiment of the invention includes a product including a pressurized gas storage vessel shell including an interior surface and an exterior surface, a liner layer over the interior surface of the pressurized gas storage vessel, and a permeation protection layer over the liner layer.

### TECHNICAL FIELD

The field to which the disclosure generally relates includes storage vessels for storing a pressurized gas such as hydrogen and methods of making thereof.

### BACKGROUND

Hydrogen is commonly used in industrial applications, for example in fuel cells. Hydrogen used in such applications may be stored in a pressurized storage vessel. Storage vessels for compressed gases must have mechanical stability and integrity so that the container does not rupture or burst from the pressure within. For fuel cell vehicles, it is typically desirable to make hydrogen gas containers lightweight so as not to significantly affect the weight requirements of a vehicle. It is known to use type 4 compressed gas tanks for storing compressed hydrogen gas on the vehicle. A type 4 tank includes an outer structural layer made of a synthetic material and a plastic liner. The outer layer provides the structural integrity of the tank for the pressure contained therein, and the plastic liner provides a gas tight vessel for sealing the gas therein. The plastic liner may have a median diameter of about 390 mm, a thickness of about 10 mm, a length of about 700 mm, a density of about 2.7 g/cm³, and a weight of about 8.5 kg. The rate of permeation of hydrogen through the liner may be inversely proportional to the thickness of the liner. But a thick liner reduces the volumetric capacity of the vessel.

### SUMMARY OF EXEMPLARY EMBODIMENTS OF THE INVENTION

One embodiment includes a product including a pressurized gas storage vessel shell including an interior surface and an exterior surface, a liner layer over the interior surface of the pressurized gas storage vessel, and a permeation protection layer over the liner layer.

Other exemplary embodiments of the invention will become apparent from the detailed description provided hereinafter. It should be understood that the detailed description and specific examples, while disclosing exemplary embodiments of the invention, are intended for purposes of illustration only and are not intended to limit the scope of the invention.

### BRIEF DESCRIPTION OF THE DRAWINGS

Exemplary embodiments of the present invention will become more fully understood from the detailed description and the accompanying drawings, wherein:

FIG. 1 is a sectional view of a portion of a high pressure gas storage vessel according to one embodiment of the invention.

FIG. 2A illustrates a method according to one embodiment of the invention.

FIG. 2B illustrates a method according to one embodiment of the invention.

FIG. 2C illustrates a method according to one embodiment of the invention.

### DETAILED DESCRIPTION OF EXEMPLARY EMBODIMENTS

The following description of the embodiment(s) is merely exemplary in nature and is in no way intended to limit the invention, its application, or uses.

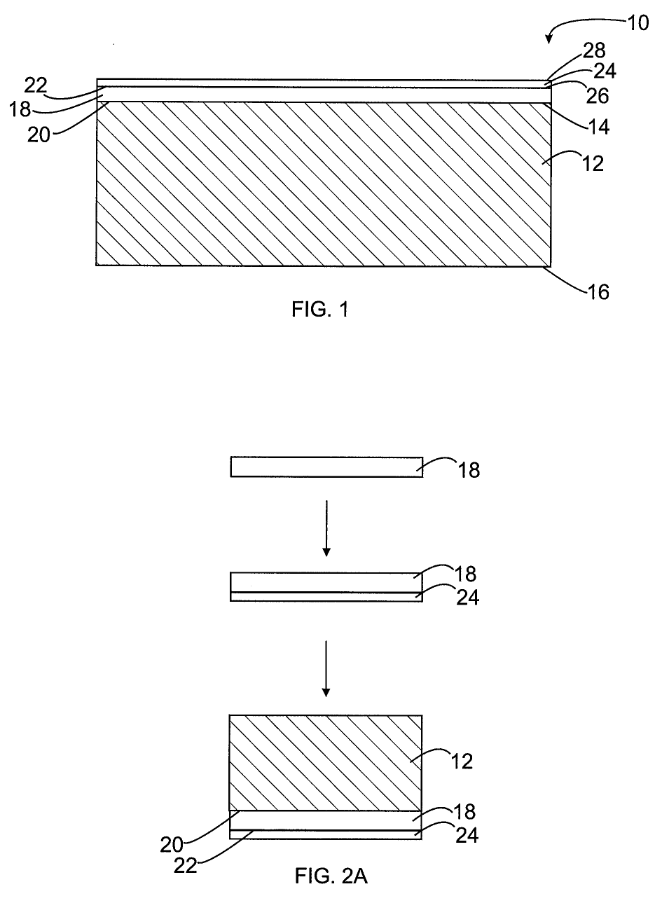

FIG. 1 is a partial sectional view of a pressurized gas storage vessel 10, according to one embodiment of the invention. The storage vessel 10 may be closed with a valve in any of a variety on design arrangements know to those skilled in the art. The storage vessel 10 includes a vessel shell 12. The vessel shell 12 has an interior surface 14 and an exterior surface 16. In one embodiment, the vessel shell 12 may be a synthetic material, such as but not limited to carbon fiber, glass fiber, or a composite fiber matrix. The interior of the vessel 10 is suitable for containing pressurized gas, for example hydrogen. In one embodiment, the pressurized hydrogen may be consumed in a fuel cell. In other embodiments, the storage vessel 10 may be adapted to contain other pressurized gases for a variety of uses.

Still referring to FIG. 1, a liner layer 18 overlies the interior surface 14 of the vessel shell 12. In one embodiment, the vessel shell 12 may be wrapped around the liner layer 18. In one embodiment, the liner layer 18 may be wrapped around the vessel shell 12. In one embodiment, the liner layer 18 may be a synthetic material. In one embodiment, the liner layer 18 may be plastic. In one embodiment, the liner layer 18 may be a low-cost plastic. The liner layer 18 has a first surface 20 and a second surface 22. The first surface 20 may be in contact with the interior surface 14 of the vessel shell 12. In one embodiment, liner layer has a thickness of about 1 to about 20 mm. In another embodiment, the liner layer has a thickness of about 3 to about 12 mm. In one embodiment, the liner layer 18 may provide a support framework for the storage vessel 10. In one embodiment shown in FIG. 1, the liner layer 18 may not come into contact with the stored gas in the storage vessel 10. In one embodiment, the liner layer 18 includes, but is not limited to, a polymeric material, for example, high-density polyethylene. In various embodiments, the liner layer 18 may be able to withstand a wide range of operating temperatures, pressures, and pressurized gas concentrations.

In one embodiment, a permeation protection layer 24 overlies the liner layer 18. In one embodiment, the permeation protection layer 24 may be described as a coating over the liner layer 18. In one embodiment, the liner layer 18 may be a malleable support structure or platform for the permeation protection layer 24, while the permeation protection layer 24 prevents or decreases the permeation of gas from the storage vessel 10. The permeation protection layer 24 has a first surface 26 and a second surface 28. In one embodiment shown in FIG. 1, the first surface 26 may be in contact with the second surface 22 of the liner layer 18. The permeation protection layer 24 may accommodate the mechanical requirements of various operating temperatures, pressures, etc. in the storage vessel 10.

In one embodiment, the permeation protection layer 24 may be one of glass, SiO₂, titanium oxide, amorphous hydrogenated Diamond Like Carbon (DLC), a metal from the fourth to eighth subgroups of the Periodic Table of Elements, or a combination of metals from the fourth to eighth subgroups of the Periodic Table of Elements. In one embodiment, the permeation protection layer has a thickness of about 10 nm to about 5 μm. In another embodiment, the permeation protection layer has a thickness of about 100 nm to about 1 μm. The permeation protection layer 24 may prevent the permeation of pressurized gas from the interior of the vessel. The permeation protection layer 24 may accommodate the mechanical requirements, for example temperature and pressure, for preventing the permeation of pressurized gas from the vessel interior.

In one embodiment, the combined thickness of the liner layer 18 and the permeation protection layer 24 may be less than the thickness of a conventional liner in a pressurized gas storage vessel. The volumetric storage capacity of the vessel 10 may be greater than that of a conventional pressurized gas storage vessel.

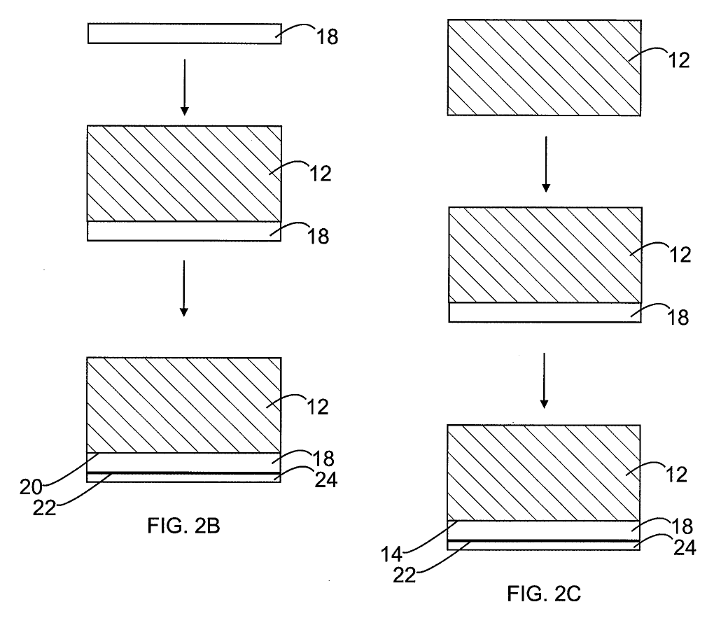

In FIGS. 2A-C, flow diagrams are shown for various methods of fabricating the storage vessel 10. Referring to FIG. 2A, in one embodiment the liner layer 18 is provided. Then the permeation protection layer 24 is provided over the second surface 22 of the liner layer 18. In one embodiment, the permeation protection layer 24 may be formed over the second surface 22 of the liner layer 18 using a deposition technique such as, but not limited to, chemical vapor deposition, plasma activated chemical vapor deposition, or physical vapor deposition. Then the vessel shell 12 may be provided over the first surface 20 of the liner layer 18.

According to another embodiment shown in FIG. 2B, the liner layer 18 is provided. Then the vessel shell 12 may be provided over the first surface 20 of the liner layer 18. In one embodiment, the vessel shell 12 may be wrapped around the liner layer 18 in an automated or manual wrapping process. Then the permeation protection layer 24 may be provided over the second surface 22 of the liner layer 18. As described above, the permeation protection layer 24 may be formed using a deposition technique.

According to another embodiment shown in FIG. 2C, the vessel shell 12 is provided. Then the liner layer 18 may be provided over the interior surface 14 of the vessel shell 12. In one embodiment, the liner layer 18 may be wrapped around the vessel shell 12 in an automated or manual wrapping process. Then the permeation protection layer 24 may be provided over the second surface 22 of the liner layer 18. As described above, the permeation protection layer 24 may be formed using a deposition technique.

In one embodiment, the storage vessel 10 may be installed in a fuel cell vehicle (not shown). Gaseous pressurized hydrogen may be stored in the storage vessel 10. The pressurized hydrogen may be distributed from the interior of the vessel to a fuel cell stack (not shown), where the hydrogen may be used as fuel to generate electrical power for the fuel cell vehicle.

The above description of embodiments of the invention is merely exemplary in nature and, thus, variations thereof are not to be regarded as a departure from the spirit and scope of the invention.

What is claimed is:

1. A product comprising:
a pressurized gas storage vessel shell comprising an interior surface and an exterior surface;
a liner layer over the interior surface of the pressurized gas storage vessel; and
a permeation protection layer over the liner layer.

2. A product as set forth in claim 1 wherein the pressurized gas storage vessel shell comprises a composite fiber matrix.

3. A product as set forth in claim 1 wherein the pressurized gas storage vessel shell comprises a glass fiber.

4. A product as set forth in claim 1 wherein the pressurized gas storage vessel shell comprises a carbon fiber.

5. A product as set forth in claim 1 wherein the liner layer comprises plastic.

6. A product as set forth in claim 1 wherein the permeation protection layer comprises one of SiO₂, amorphous hydrogenated Diamond Like Carbon (DLC), a metal from the fourth to eighth subgroups of the Periodic Table of Elements, or a combination of metals from the fourth to eighth subgroups of the Periodic Table of Elements.

7. A product as set forth in claim 1 wherein the liner layer has a thickness of about 1 to about 20 mm.

8. A product as set forth in claim 1 wherein the liner layer has a thickness of about 3 to about 12 mm.

9. A product as set forth in claim 1 wherein the permeation protection layer has a thickness of about 10 nm to about 5 μm.

10. A product as set forth in claim 1 wherein the permeation protection layer has a thickness of about 100 nm to about 1 μm.

11. A method comprising:
providing a pressurized gas storage vessel shell comprising an interior surface and an exterior surface;
providing a liner layer over the interior surface of the pressurized gas storage vessel; and
providing a permeation protection layer over the liner layer.

12. A method as set forth in claim 11 wherein the providing the permeation protection layer comprises one of chemical vapor deposition, plasma activated chemical vapor deposition, or physical vapor deposition.

13. A method as set forth in claim 11 wherein the providing the liner layer comprises one of automated wrapping or manual wrapping over the interior surface of the pressurized gas storage vessel.

14. A method as set forth in claim 11 wherein the pressurized gas storage vessel shell comprises a composite fiber matrix.

15. A method as set forth in claim 11 wherein the pressurized gas storage vessel shell comprises a glass fiber.

16. A method as set forth in claim 11 wherein the pressurized gas storage vessel shell comprises a carbon fiber.

17. A method as set forth in claim 11 wherein the liner layer comprises plastic.

18. A method as set forth in claim 11 wherein the permeation protection layer comprises one of SiO₂, amorphous hydrogenated Diamond Like Carbon (DLC), a metal from the fourth to eighth subgroups of the Periodic Table of Elements, or a combination of metals from the fourth to eighth subgroups of the Periodic Table of Elements.

19. A method as set forth in claim 11 wherein the liner layer has a thickness of about 1 to about 20 mm.

20. A method as set forth in claim 11 wherein the liner layer has a thickness of about 3 to about 12 mm.

21. A method as set forth in claim 11 wherein the permeation protection layer has a thickness of about 10 nm to about 5 μm.

22. A method as set forth in claim 11 wherein the permeation protection layer has a thickness of about 100 nm to about 1 μm.
